(19) United States
(12) Patent Application Publication
(10) Pub. No.: US 2004/0026715 A1
(43) Pub. Date: Feb. 12, 2004

(54) Package for a non-volatile memory device including integrated passive devices and method for making the same

(76) Inventors: Eleanor P. Rabadam, Folsom, CA (US); Michael J. Walk, Mesa, AZ (US); Milan Keser, Chandler, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/430,121

(22) Filed: May 5, 2003

Related U.S. Application Data
(63) Continuation-in-part of application No. 10/039,454, filed on Dec. 28, 2001.

(51) Int. Cl. H01L 27/10

(52) U.S. Cl. 257/202

(57) ABSTRACT

Briefly, in accordance with one embodiment of the invention, a memory device package includes an integrated circuit die having a memory array and at least one passive component mounted to a substrate. In alternative embodiments, an array of solder balls may be mounted around the passive component.

### BACKGROUND

Memory devices such as, for example, non-volatile memory devices often involve the use of programming/erasing voltage potentials that are typically different that the normal operating voltage potentials. As a result, the memory devices may be connected to additional circuitry that generates and regulates the voltage potentials used to program or erase the memory device. However, the additional circuitry may increase the cost associated with the memory devices. The additional circuits and components may also affect the reliability of the memory device as there as more components involved whose failures may result in a failure of the operation of the memory.

Thus, there is a continuing need for better ways to package memory devices.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a cross-sectional view of a package in accordance with an embodiment of the present invention;

FIG. 2 is an alternative view of the package shown in FIG. 1; and

FIGS. 3 and 4 are cross-sectional views of packages in accordance with alternative embodiments of the present invention.

It will be appreciated that for simplicity and clarity of illustration, elements illustrated in the figure have not necessarily been drawn to scale. For example, the dimensions of some of the elements are exaggerated relative to other elements for clarity.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

In the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

Turning to FIG. 1, an embodiment 100 in accordance with the present invention is described. A ball grid array (BGA) package 26 may include a substrate 28 that may be electrically coupled to external circuitry using a multiplicity of solder balls 34. It should be understood that the scope of the present invention is not limited to BGA packages, as other packages may be alternatively used.

Package 26 may contain an integrated circuit die 29 attached to the substrate 28, for example using a suitable adhesive. The adhesive may comprise a non-conductive material so as to provide electrical isolation between substrate 28 and integrated circuit die 29. Alternatively, the adhesive may comprise a conductive material so as to electrically couple integrated circuit 29 to substrate 28 or the underlying solder balls 34.

Although the scope of the present invention is not limited in this respect, integrated circuit die 29 may include a non-volatile memory array such as an electrically programmable read-only memory (EPROM), electrically erasable and programmable read only memory (EEPROM), single-bit flash memory, multi-bit flash memory, etc.

In one embodiment, all or a portion of a voltage regulator circuit may be formed underlying package 26. The voltage regulator may be used to provide voltage potentials to be used during the operation of integrated circuit die 29. For example, although the scope of the present invention is not limited in this respect, the voltage regulator may provide voltage potentials to program and/or erase the non-volatile memory within integrated circuit die 29.

Although the scope of the present invention is not limited in this respect passive components 60-61 may be mounted to substrate 28 underlying integrated circuit die 29. For example passive components 60-61 may include components such as capacitors, inductors, resistive elements, or other integrated components associated with charge pump circuitry, voltage regulator circuitry, etc. Although this list is not meant to be exhaustive as any number of active or passive devices may be molded in package 26 if desired.

Passive components 60-61 may be mounted or attached to the underlying surface of substrate 28 using, for example using an adhesive 18. Adhesive 18 may comprise a non-conductive material such as, for example, an epoxy so as to provide electrical isolation between passive components 60 and 61 and substrate 28. Although the scope of the present invention is not limited in this respect, for in alternative embodiments, adhesive 18 may comprise some conductive material (e.g. solder paste) so as to electrically couple passive components 60-61 to integrated circuit die 29. The thickness of adhesive layer may be varied as desired, but may be less than about 0.1 millimeters so as to reduce the overall thickness of package 26.

Wire bonds 20 may be formed between integrated circuit die 29 and substrate 28 as shown in FIG. 1. Alternatively, or in addition to, wire bonds 20 may be formed between passive components 60-61 and substrate 28. Wire bonds 20 may provide electrical connection to integrated circuit die 29, substrate 28 and/or any of the underlying solder balls 34. Although the scope of the present invention is not limited in this respect, integrated circuit die 29 may be molded in a non-conductive encapsulant 24 to form a molded array package (MAP).

Although only a few passive components are shown in FIG. 1, it should be understood that in alternative embodiments just one or all the passive components associated with the operation of integrated circuit die 29 may be mounted to substrate 28. In addition, it should be understood that the scope of the present invention is not limited in application to only non-volatile memory devices, or only to memory devices in general.

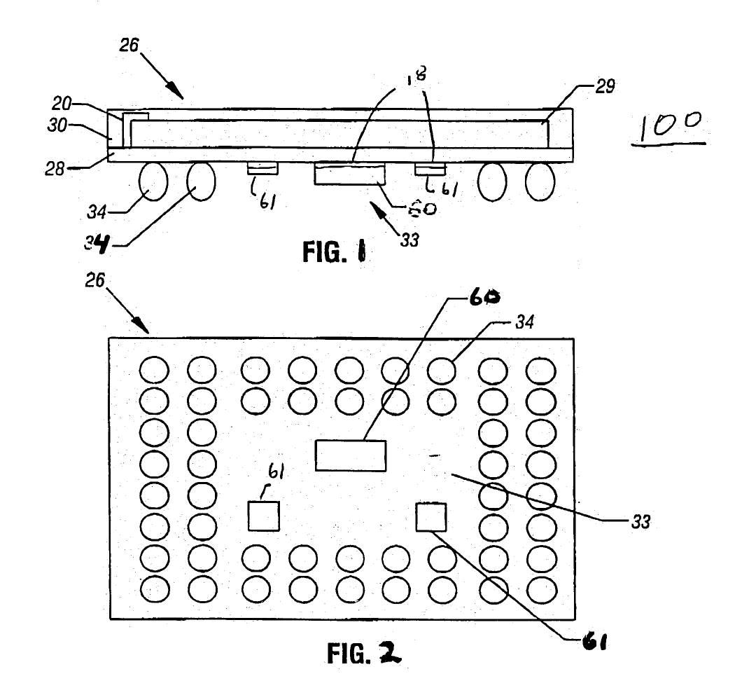

As shown in FIG. 2, passive components 60-61 may be mounted so that they are centrally located 33 within an array of solder balls 34, although the scope of the present invention is not limited in this respect. This may be desirable so as to enable footprint compatibility with existing non-PSIP packages and save on cost of new test hardware and printed circuit boards. However, in alternative embodiments, passive components 60-61 may be placed external to the array of solder balls 34. In addition, passive components 60-61 may be placed anywhere on the underlying surface of substrate 28 to take into account such factors as heat dissipation or the electrical noise/ interference the components may create.

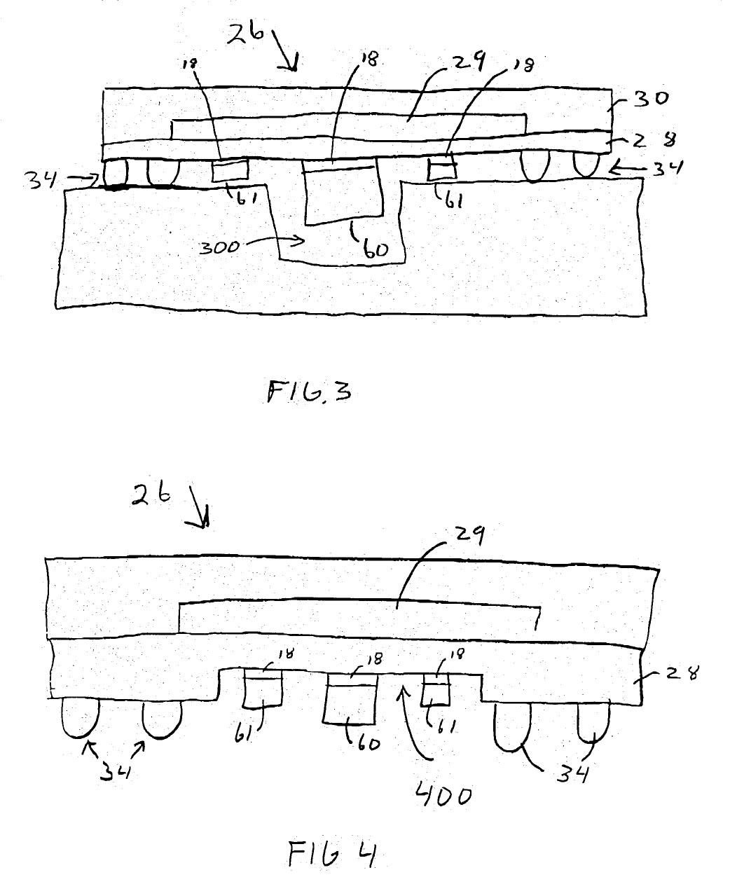

In addition, it may be desirable to select the size of passive components and/or solder balls 34 so that the height of passive components 60-61 is less than the height of solder balls 34 so that passive components 60-61 do not interfere with mounting package 26 to other components or boards, although the scope of the present invention is not limited in this respect. In other embodiments of the present invention, such as those shown in FIG. 3, passive components 60-61 may have a height greater than solder balls 34 (i.e. passive components 60-61 extended further outward from substrate 28). The height may be compensated for by having a cavity 300 or other recess in the location on the printed circuit board corresponding to passive components 60 so that passive components 60-61 do not interfere with the use and mounting of package 26.

Turning to FIG. 4, yet another embodiment of the present invention is described. To further reduce the risk that passive components 60-61 would interfere with the mounting of BGA package 26, it may be desirable to mount passive components 60-61 in a cavity 400 in substrate 28. Cavity 400 may be formed in a variety of ways. For example, although the scope of the present invention is not limited in this respect, cavity 400 may be machined, pressed, or etched out of substrate 28. Alternatively, substrate 28 may be formed by combining several substrates that have different thicknesses.

Accordingly, the embodiments illustrated in the figures demonstrate a power supply in package (PSIP arrangement where at least portions of the circuitry or components associated with the operation of integrated circuit die 29 may be mounted to substrate 28.) Package 26 may substantially maintain the form factor of corresponding non-PSIP packages (e.g. separate packages for the memory device, for the passive components, and for the voltage regulator) so that package 26 may fit within the space allocated on boards for corresponding non-PSIP packages that perform substantially the same features. As a result, a compact package 26 may be achieved that has lower manufacturing costs while substantially maintaining the form factor of corresponding (but more expensive) non-PSIP packages.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

1. A non-volatile memory package comprising:
a substrate having a first surface and a second surface, the first surface overlying the second surface;
an integrated circuit die including a memory array mounted to the first surface of the substrate; and
a passive component mounted to the second surface of the substrate.

2. The non-volatile memory package of claim 1, wherein the passive component is electrically coupled to the integrated circuit die.

3. The non-volatile memory package of claim 1, further comprising an array of solder balls mounted to the substrate.

4. The non-volatile memory package of claim 3, wherein the passive component is located centrally within the array of solder balls.

5. The non-volatile memory package of claim 4, wherein the passive component has a height less than a height of the solder balls.

6. The non-volatile memory package of claim 1, wherein the passive component is at least a portion of a voltage regulator circuit coupled to the integrated circuit die.

7. The non-volatile memory package of claim 1, wherein the substrate comprises a cavity and at least a portion of the passive component lies within the cavity.

8. The non-volatile memory package of claim 7, further comprising an array of solder balls mounted to the substrate, wherein the passive component has a height less than a height of the solder balls.

10. The non-volatile memory package of claim 1, wherein the passive component is mounted to the second surface of the substrate with an epoxy material.

11. The non-volatile memory package of claim 10, wherein the epoxy material between the passive component and the substrate is less than about 0.1 millimeters in thickness.

12. The non-volatile memory package of claim 1, wherein the passive component is mounted to the second surface of the substrate with a conductive material.

13. The non-volatile memory package of claim 1, wherein the passive component includes a capacitor or an inductor.

14. The memory device of claim 1, wherein the integrated circuit die includes a flash memory array.

15. The memory device of claim 1, further comprising a plurality of passive devices mounted to the second surface of the substrate.

16. A method of packaging a non-volatile memory comprising:
providing a substrate having a first surface and a second surface;
mounting the non-volatile memory to the first surface of the substrate; and
mounting a passive component to the second surface of the substrate.

17. The method of claim 16, further comprising:
mounting an array of solder balls around the passive component to the second surface of the substrate.

18. The method of claim 16, wherein mounting the passive component includes mounting the passive component within a cavity in the substrate.

19. A method comprising:
mounting an integrated circuit comprising a non-volatile memory array to a first surface of a substrate; and
mounting at least a portion of a voltage regulator to a second surface of the substrate, the voltage regulator being electrically coupled to the non-volatile memory array.

20. The method of claim 19, further comprising mounting an array of solder balls to the second surface of the substrate.

21. The method of claim 19, wherein mounting at least a portion of the voltage regulator includes mounting a passive component to the second surface of the substrate.

22. The method of claim 21, wherein mounting a passive component to the second surface includes mounting the passive component in a cavity in the substrate.
